(19) United States
(12) Patent Application Publication
(10) Pub. No.: US 2010/0144146 A1
(43) Pub. Date: Jun. 10, 2010

(54) METHOD FOR FABRICATING SEMICONDUCTOR DEVICE

(76) Inventors: Koji UTAKA, Hyogo (JP); Yoshiharu HIDAKA, Osaka (JP); Kenji NARITA, Osaka (JP)

Correspondence Address: MCDERMOTT WILL & EMERY LLP, 600 13TH STREET, NW, WASHINGTON, DC, 20005-3096, US

(21) Appl. No.: 12/627,572

(22) Filed: Nov. 30, 2009

(30) Foreign Application Priority Data
Dec. 3, 2008 (JP) 2008-308137
Aug. 20, 2009 (JP) 2009-190917

(51) Int. Cl. H01L 21/30

(52) U.S. Cl. 438/682; 257/E21.158; 257/E21.211

(57) ABSTRACT

The step a) of forming a noble metal film or a metal film containing a noble metal on a semiconductor substrate containing silicon or a conductive film containing silicon is performed, the step b) of forming a silicide film containing a noble metal on the semiconductor substrate or the conductive film is performed, after the step a), by performing thermal treatment to the semiconductor substrate, the step c) of activating unreacted part of the noble metal using a first chemical solution is performed after the step b), and the step d) of dissolving the unreacted part of the noble metal activated in the step c) is performed. The step d) is performed within 30 minutes or less after the step c).

### CROSS-REFERENCE TO RELATED APPLICATION

This application claims priority to Japanese Patent Application No. 2008-308137 filed on Dec. 3, 2008, and Japanese Patent Application No. 2009-190917 filed on Aug. 20, 2009, the disclosure of which including the specification, the drawings, and the claims is hereby incorporated by reference in its entirety.

### BACKGROUND

The present disclosure relates to a method for fabricating a semiconductor device, and more particularly relates to a method for fabricating a semiconductor device including a silicide layer containing a noble metal, an electrode containing a noble metal or the like.

There is a need to further improve the performance of devices and reduce the power consumption thereof in CMOS (complementary metal-oxide semiconductor) microfabrication process. In such a circumstance, in a known CMOS process, NiSi containing Ni or CoSi containing Co is used as a silicide material in order to further reduce a silicide resistance.

However, in microfabrication process, a silicide reaction of NISI or CoSi has to be reduced in order to reduce a junction leakage current. Therefore, as a silicide material, an alloy of Ni or Co with about 5-10% of Pt or Pd is used. Specifically, when an alloy (NiPt) of Ni and Pt is used as a silicide maternal, the effect of improving a heat resistance and reducing a junction leakage current can be expected.

In the step of silicidation, after an alloy film is formed on a Si substrate, thermal oxidation is performed to the substrate to cause the alloy to react with Si, thereby forming silicide. In this step, residual, unreacted part of the alloy has to be removed. For example, when an alloy (NiPt) of Ni and Pt is used as a silicide material, an acid, such as a mixture solution of sulfuric acid and hydrogen peroxide water, having high oxidative power is used to remove unreacted NiPt after silicide is formed (see, for example, Japanese Published Patent Application No. 2002-124487).

FIGS. 11A and 11B are cross-sectional views illustrating known steps for forming silicide. In the step shown in FIG. 11A, after a semiconductor substrate 123 of silicon is prepared so that part of an upper surface of the semiconductor substrate 123 is exposed as a silicide formation region, an insulation film 124 is formed on a non-silicide region of the semiconductor substrate 123, and then, an NiPt 125, as a silicide material, is formed over the entire semiconductor substrate 123. Thereafter, thermal oxidation is performed to the substrate, thereby forming a silicide layer 126, which is a mixed crystal of NiSi and NiPtSi, in a silicide region. Note that mixed crystals of NiSi and NiPtSi are collectively called NiPtSi.

Next, in the step shown in FIG. 11B, unreacted part of the NiPt 125 is removed to leave only NiPtSi. In this step, the unreacted part of the NiPt 125 is removed using a mixture solution 127 of sulfuric acid and hydrogen peroxide water.

However, in the silicide formation process, when an acid such as a mixture solution of sulfuric acid and hydrogen peroxide water, having high oxidative power is used to remove the unreacted part of the NiPt 125, Ni can be dissolved, but Pt, which is chemically-unreactive, cannot be dissolved and remains on the semiconductor substrate. Therefore, to prevent Pt from remaining undissolved, instead of the mixture solution 127, aqua regia (i.e., a solution containing nitric acid and hydrochloric acid) having higher oxidative power than the mixture solution 127 is used (see, for example, Japanese Published Patent Application No. 2008-118088).

In recent years, ferroelectric memories (FeRAM) or logic LSIs with a ferroelectric memory for use in IC cards, general-purpose microcomputer and the like have been practically used in a wider range. Specifically, ferroelectric films such as PZT (Pb(ZrTi)O₃), SBT (SrBi₂Ta₂O₉) or the like are used as capacitive films of FeRAMs.

### SUMMARY

However, when such a ferroelectric film is directly in contact with a substrate, the substrate is oxidized, and thus capacitance characteristics thereof are degraded. Therefore, when such a ferroelectric film is used, a noble metal which does not react with the ferroelectric film is used as a lower capacitive electrode and an upper capacitive electrode. In particular, Pt, which is one of such noble metals, is used as an upper electrode and a lower electrode in many cases. When Pt is used as a lower electrode and an upper electrode in forming a capacitor device, a Pt film is formed in the step of forming the lower electrode and the upper electrode, and in the course of this step, a Pt contaminant is attached to a back surface of the substrate. If the Pt contaminant of about 1×10¹⁰ atom/cm² remains on the back surface of the substrate or an insulation film on the back surface of the substrate, the lifetime and electric characteristics of the capacitor device are adversely affected.

Therefore, it is necessary to remove the Pt contaminant from the back surface of the substrate. However, since Pt is dissolved only in aqua regia, the Pt contaminant cannot be reduced even using SPM (sulfuric acid peroxide mixture solution) or HPM (hydrochloric acid peroxide mixture solution), which are general metal removal solutions. Therefore, aqua regia is used to reduce the Pt contaminant on the back surface of the substrate. Aqua regia is also used to remove an unnecessary Pt film by dissolving using wet etching both in forming the lower electrode and in forming the upper electrode.

However, when dissolving residual Pt, the Pt contaminant or the Pt film using aqua regia (a solution containing nitric acid and hydrochloric acid) or dilute aqua regia, the following problems arise.

Aqua regia is capable of dissolving Pt as a chloride salt by oxidative power of nitrosyl chloride in aqua regia. However, it takes 1-2 hours from a time when aqua regia is prepared, for the concentration of nitrosyl chloride to stabilize after nitrosyl chloride is formed. Also, after the preparation of aqua regia, the concentration of nitrosyl chloride is reduced with time, and after the elapsed time since the preparation of aqua regia exceeds 20 hours, the etching rate of Pt is drastically reduced, so that Pt is not practically dissolved. That is, to ensure the Pt dissolving ability, it is necessary to wait for 2 hours from the preparation of aqua regia without using a chemical solution, and also, solution exchange is required after a lapse of 20 hours since the preparation of aqua regia. Because such waiting time or frequent solution exchange are required, the operation rate of an etching apparatus is drastically reduced. Moreover, aqua regia is highly corrosive, and thus, corrosion of metal parts of the etching apparatus cannot be completely prevented even though corrosion prevention measures are taken for the etching apparatus. Therefore, the metal parts have to be frequently exchanged at short intervals.

According to illustrative embodiments of the present invention, in fabricating a semiconductor device, residual Pt, a Pt contaminant or a Pt film can be effectively etched, and also, progression of corrosion on metal parts of an etching apparatus can be reduced.

To solve the above-described problems, a first method for fabricating a semiconductor device according to an example of the present invention includes the steps of: a) forming a metal film containing a noble metal on a substrate including a semiconductor layer containing silicon or a conductive film containing silicon formed on the substrate; b) forming, after the step a), a silicide film containing the noble metal on the substrate or the conductive film by performing thermal treatment to the substrate to cause the noble metal and silicon react with each other; c) activating, after the step b), unreacted part of the noble metal using a first chemical solution; and d) dissolving the unreacted part of the noble metal activated in the step c) using a second chemical solution, and the step d) is performed within 30 minutes after performing the step c).

According to this method, compared to the case where only the step of dissolving the noble metal is performed after the silicide film is formed, a residue containing a noble metal can be effectively removed. Moreover, in the step d), the unreacted part of the noble metal being activated can be removed. Thus, even when the concentration of an active element in the second chemical solution is low, the noble metal can be removed, so that the second chemical solution can be used for a longer period of time, compared to a known method. Furthermore, since treatment using the second chemical solution can be performed at a lower temperature, compared to the known method, corrosion of metal parts of an etching apparatus can be reduced, and also evaporation and alteration of the second chemical solution can be reduced.

The noble metal may be platinum (Pt), the first chemical solution may be a mixture solution of a sulfuric acid based solution and an oxidant, and the second chemical solution may be a mixture solution of a hydrochloric acid based solution and an oxidant. In this case, silicide containing Pt can be formed while preventing contamination with Pt.

It is preferable that the first chemical solution is a solution selected from the group consisting of a mixture solution of sulfuric acid and hydrogen peroxide water, a mixture solution of sulfuric acid and ozone water, and an electrolytic sulfuric acid solution.

It is preferable that, in the step c), the first chemical solution is used at a solution temperature of 80° C. or more.

It is preferable that a mix ratio of sulfuric acid and hydrogen peroxide water in the mixture solution of sulfuric acid and hydrogen peroxide water as the first chemical solution is 1-5:1, or a mix ratio of sulfuric acid and ozone water in the mixture solution of sulfuric acid and ozone water as the first chemical solution is 1-5:1.

It is preferable that the second chemical solution is a solution selected from the group consisting of a mixture solution of nitric acid and hydrochloric acid, a mixture solution of hydrochloric acid and hydrogen peroxide water, a mixture solution of hydrochloric acid and ozone water, a solution obtained by mixing potassium permanganate to hydrochloric acid, a solution obtained by mixing chromium trioxide to hydrochloric acid, a solution obtained by mixing potassium chlorate to hydrochloric acid, a solution obtained by mixing osmium tetraoxide to hydrochloric acid, and a dilute solution of any one of the solutions.

It is preferable that, in the step c), the second chemical solution is used at a solution temperature of 40° C. or more because, by this method, corrosion of an etching apparatus can be effectively suppressed.

It is preferable that a mix ratio of nitric acid and hydrochloric acid in the mixture solution of nitric acid and hydrochloric acid is 1:3-7, a mix ratio of hydrochloric acid and hydrogen peroxide water in the mixture solution of hydrochloric acid and hydrogen peroxide water is 3-5:1, a mix ratio of hydrochloric acid and ozone water in the mixture solution of hydrochloric acid and ozone water is 3-5:1, the solution obtained by mixing potassium permanganate to hydrochloric acid is a solution obtained by mixing 1-7 wt % of potassium permanganate to hydrochloric acid, the solution obtained by mixing chromium trioxide to hydrochloric acid is a solution obtained by mixing 1-5 wt % of chromium trioxide to hydrochloric acid, the solution obtained by mixing potassium chlorate to hydrochloric acid is a solution obtained by mixing 1-7 wt % of potassium chlorate to hydrochloric acid, the solution obtained by mixing osmium tetraoxide to hydrochloric acid is a solution obtained by mixing 1-6 wt % of osmium tetraoxide to hydrochloric acid, and a dilution degree in the dilute solution of any one of the solutions is 7-fold or less.

A second method for fabricating a semiconductor device according to another example of the present invention includes the steps of: a) forming a first metal film containing a first noble metal on an interlevel insulation film formed on a substrate; b) removing, after the step a), a contaminant containing the first noble metal attached to a back surface of the substrate; c) forming, after the step a), a lower electrode by selectively removing the first metal film; d) forming a capacitive insulation film on the lower electrode; e) forming a second metal film containing a second noble metal on the capacitive insulation film and the substrate; f) removing, after the step e), a contaminant containing the second noble metal attached to the back surface of the substrate; and g) forming, after the step e), an upper electrode by selectively removing the second metal film.

According to this method, a contaminant containing a noble metal attached to the back surface of the substrate can be removed in the steps of b) and f). Thus, a highly reliable semiconductor device can be fabricated.

It is preferable that the step b) is performed simultaneously with the step c), and in the step b) and the step c), the first noble metal is activated using a mixture solution of a sulfuric acid based solution and an oxidant as a first chemical solution, and then, the first noble metal is dissolved using a mixture solution of a hydrochloric acid based solution and an oxidant as a second chemical solution, and the step f) is performed simultaneously with the step g), and in the step f) and step g), the second noble metal is activated using the first chemical solution, and then, the second noble metal is dissolved using the second chemical solution, because, by this method, the contaminant on the back surface of the substrate can be effectively removed while forming the lower electrode and the upper electrode.

It is preferable that, in the step b) and the step c), treatment for dissolving the first noble metal using the second chemical solution is performed within 30 minutes or less after treatment for activating the first noble metal using the first chemical solution, and in the step f) and the step g), treatment for dissolving the second noble metal using the second chemical solution is performed within 30 minutes or less after treatment for activating the second noble metal using the first chemical solution.

According to a third method for fabricating a semiconductor device according to still another example of the present invention includes the steps of: a) forming a first metal film containing a first noble metal, an insulation film and a second metal film containing a second noble metal in this order on an interlevel insulation film formed on a substrate: b) forming a lower electrode of the first metal film, a capacitive insulation film of the insulation film, and an upper electrode of the second metal film by selectively removing parts of the second metal film, the insulation film, and the first metal film together at a time; and c) removing, after the step of b), a contaminant containing the first noble metal and the second noble metal attached to a back surface of the substrate.

According to this method, a contaminant containing the first noble metal and the second noble metal, attached to the back surface of the substrate can be removed after a capacitor is formed in the step b). Thus, a highly reliable semiconductor device or the like can be fabricated.

Moreover, it is preferable that, in the step c), the first noble metal and the second noble metal are activated using a mixture solution of a sulfuric acid based solution and an oxidant as a first chemical solution, and the first noble metal and the second noble metal are dissolved using a mixture solution of a hydrochloric acid based solution and an oxidant as a second chemical solution.

It is preferable that, in the step c), treatment for dissolving the first noble metal and the second noble metal using the second chemical solution is performed within 30 minutes or less after treatment for activating the first noble metal and the second noble metal using the first chemical solution.

It is preferable that the first chemical solution is a solution selected from the group consisting of a mixture solution of sulfuric acid and hydrogen peroxide water, a mixture solution of sulfuric acid and ozone water, and an electrolytic sulfuric acid solution.

It is preferable that the first chemical solution is used at a solution temperature of 80° C. or more.

It is preferable that a mix ratio of sulfuric acid and hydrogen peroxide water in the mixture solution of sulfuric acid and hydrogen peroxide water as the first chemical solution is 1-5:1, or a mix ratio of sulfuric acid and ozone water in the mixture solution of sulfuric acid and ozone water as the first chemical solution is 1-5:1.

The second chemical solution may be a solution selected from the group consisting of a mixture solution of nitric acid and hydrochloric acid, a mixture solution of hydrochloric acid and hydrogen peroxide water, a mixture solution of hydrochloric acid and ozone water, a solution obtained by mixing potassium permanganate to hydrochloric acid, a solution obtained by mixing chromium trioxide to hydrochloric acid, a solution obtained by mixing potassium chlorate to hydrochloric acid, a solution obtained by mixing osmium tetraoxide to hydrochloric acid, and a dilute solution of any one of the solutions.

It is preferable that the second chemical solution is used at a solution temperature of 40° C. or more.

A mix ratio of nitric acid and hydrochloric acid in the mixture solution of nitric acid and hydrochloric acid may be 1:3-7, a mix ratio of hydrochloric acid and hydrogen peroxide water in the mixture solution of hydrochloric acid and hydrogen peroxide water may be 3-5:1, a mix ratio of hydrochloric acid and ozone water in the mixture solution of hydrochloric acid and ozone water may be 3-5:1, the solution obtained by mixing potassium permanganate to hydrochloric acid may be a solution obtained by mixing 1-7 wt % of potassium permanganate to hydrochloric acid, the solution obtained by mixing chromium trioxide to hydrochloric acid may be a solution obtained by mixing 1-5 wt % of chromium trioxide to hydrochloric acid, the solution obtained by mixing potassium chlorate to hydrochloric acid may be a solution obtained by mixing 1-7 wt % of potassium chlorate to hydrochloric acid, the solution obtained by mixing osmium tetraoxide to hydrochloric acid may be a solution obtained by mixing 1-6 wt % of osmium tetraoxide to hydrochloric acid, and a dilution degree in the dilute solution of any one of the solutions may be 7-fold or less.

As has been described, according to the method for fabricating a semiconductor device according to any one of examples of the present invention, in dissolving residual Pt, a Pt contaminant or a Pt film using aqua regia or dilute aqua regia, the lifetime of aqua regia or dilute aqua regia can be increased, the operation rate of an etching apparatus can be improved, and also, progression of corrosion on metal parts of an etching apparatus can be suppressed.

### BRIEF DESCRIPTION OF THE DRAWINGS

FIGS. 1A-1E are cross-sectional views illustrating a method for fabricating a semiconductor device according to a first embodiment.

FIG. 2 is a potential-pH diagram of Pt for describing a method for fabricating a semiconductor device of the first embodiment.

FIG. 3 is a graph showing the relationship between the amount of Pt being etched and an elapsed time since the preparation of aqua regia for the case where the method of the first embodiment was employed and the case where a known method was employed.

FIG. 4 is a graph showing the amount of Pt being etched on a waver surface for the case where the method of the first embodiment was employed and the case where a known method was employed.

FIGS. 5A and 5B are SEM images of semiconductor substrates being cleaned according to a known method. FIG. 5C is a SEM image of a semiconductor substrate being cleaned according to the method of the first embodiment.

FIG. 6 is a graph showing the dependency of the amount of Pt being etched on a wafer surface using dilute aqua regia on an elapsed time in which the wafer is left.

FIG. 7 is a graph showing OD short-circuits which occurred when the method of the first embodiment was employed.

FIG. 8 is a graph showing the amount of Pt being etched using a mixture solution of hydrochloric acid and an oxidant for the case where the known method was employed and the case where the method of the first embodiment was employed.

FIGS. 9A-9J are cross-sectional views illustrating respective steps for fabricating a FeRAM according to a second embodiment.

FIG. 10 is a graph showing evaluation results of the amount of a Pt contaminant on a back surface of a substrate by means of ICP-MS for the case where only aqua regia treatment using dilute aqua regia was performed for 60 seconds and the case where the method of the second embodiment was employed.

FIGS. 11A and 11B are cross-sectional views illustrating known steps for forming silicide.

### DETAILED DESCRIPTION

### First Embodiment

A method for fabricating a semiconductor device according to a first embodiment of the present invention will be described with reference to the accompanying drawings.

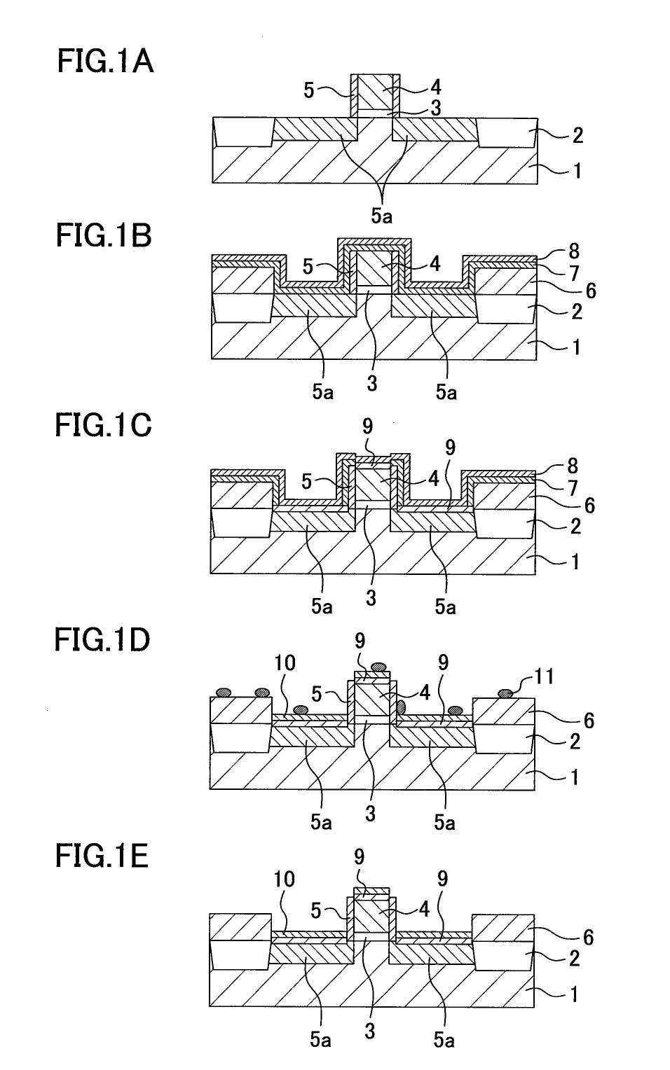

FIGS. 1A-1E are cross-sectional views illustrating a method for fabricating a semiconductor device according to the first embodiment. FIGS. 1A-1E illustrate respective steps for forming NiPt silicide as an example of silicide.

First, in the step shown in FIG. 1A, after an isolation region 2 is formed in a semiconductor substrate 1 of silicon using the STI technique or the like, a gate oxide film 3 is formed on part of the semiconductor substrate 1 surrounded by the isolation region 2, and a gate electrode (conductive film) 4 of polycrystalline silicon is formed on the gate oxide film 3. Next, using a known method, sidewalls 5 of a silicon oxide film are formed on both side surfaces of the gate electrode 4, respectively, and then, source/drain diffused layers 5a containing a high concentration of an impurity are formed in parts of the semiconductor substrate 1 located at both sides of the gate electrode 4, thereby forming a MOS transistor.

Next, in the step shown in FIG. 1B, a silicon oxide film 6 in which an impurity is not introduced is formed over an entire upper surface of the semiconductor substrate 1 so as to have a thickness of 20 to 70 nm. Then, part of the silicon oxide film 6 located on a silicide region in which a silicide reaction layer is to be formed is removed while part of the silicon oxide film 6 located on a non-silicide region in which a silicide reaction layer is not to be formed is left remaining. Thereafter, a NiPt film 7 containing 2 to 10 wt % of Pt as a silicide material is formed over the entire semiconductor substrate 1 to have a thickness of 7 to 15 nm, and then, in order to achieve a uniform silicide reaction, a TiN film 8 as a protective film is formed on the NiPt film 7 so as to have a thickness of 7 to 15 nm.

Next, in the step shown in FIG. 1C, thermal treatment is performed at a temperature of 200 to 400° C. to cause parts of the NiPt film 7 located on the source/drain diffused layers 5a and the gate electrode 4 to react with silicon of the semiconductor substrate 1, thereby forming a silicide layer 9 of NiPtSi having a thickness of 8.5 to 16.5 nm. In this thermal treatment, a silicide reaction of parts of the NiPt film 7 located over the isolation region 2 and on the part of the silicon oxide film 6 located on the non-silicide region is not caused.

Next, in the step shown in FIG. 1D, SPM treatment (H₂SO₄:H₂O₂=1-5:1, at a treatment temperature of 80° C. or more and 160° C. or less) is performed, thereby removing the TiN film 8 and unreacted part of the NiPt film 7. Thereafter, the semiconductor substrate 1 is cleaned with water, and then is dried. When SPM is used, the TiN film 8 and Ni in the NiPt film 7 can be dissolved, but Pt cannot be dissolved. Thus, Pt particles 11 are left remaining on the semiconductor substrate 1, the isolation region 2 and the gate electrode 4. Note that the above SPM composition ratio shows that concentrated sulfuric acid (H₂SO₄) having a concentration of 98 wt % and hydrogen peroxide water having a concentration of 31 wt % are mixed at a predetermined volume ratio.

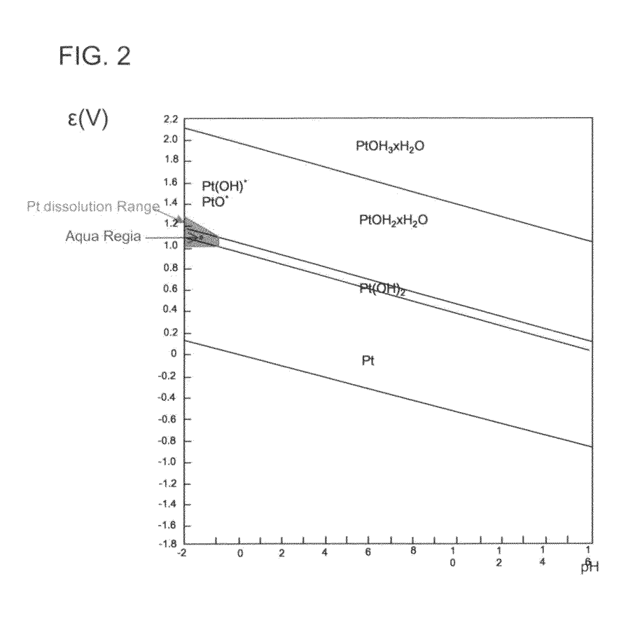

However, when SPM treatment is carried out under the above-described conditions, the TiN film 8 and Ni in the unreacted part of the NiPt film 7 is dissolved, and also, a silicon oxide film 10 for preventing a dissolution/corrosion reaction can be formed on a surface of the silicide layer 9. Moreover, when SPM treatment is carried out under the above-described conditions, as can be seen from a potential-pH diagram of FIG. 2, an oxidation-reduction potential can be caused to be 1.3 V or more in strong acid, and thus, PtO radicals and PtOH radicals can be formed. The Pt particles 11 are activated by these radials. Note that an oxidation-reduction potential of 1.3 V or more can be realized using hydrogen peroxide water. Moreover, a solution for activating the Pt particles 11 is not limited to SPM. Examples of such a solution includes a chemical solution obtained by adding an oxidant to a sulfuric acid based solution, such as, for example, a mixture solution of sulfuric acid and ozone water (H₂SO₄:O₃=1-5:1 (volume ratio), at a treatment temperature of 80° C. or more and 160° C. or less), an electrolytic sulfuric acid solution (at a treatment temperature of 80° C. or more and 100° C. or less) and the like. In this case, 98 wt % of sulfuric acid is used for generating a mixture solution of sulfuric acid and ozone water, and the ozone water has an ozone concentration of 20 ppm. Presumably, during normal cleaning with water for about 60 to 180 seconds, the activated Pt particles 11 hardly go back to a state before activation.

Next, in the step shown in FIG. 1E, the activated Pt particles 11 are dissolved with aqua regia (nitric acid:hydrochloric acid=1:3-7, at a treatment temperature of 40° C. or more and 70° C. or less) or a 7 or less fold diluted solution of aqua regia with water. Note that when only aqua regia treatment was carried out, Pt particles could not be removed unless a treatment temperature was 55° C. or more. In contrast, according to the method of this embodiment, the Pt particles 11 are activated, and thus, if a treatment temperature is 40° C. or more, the Pt particles 11 can be removed without greatly reducing an etching rate. According to the method of this embodiment, a treatment temperature in aqua regia treatment can be reduced, so that evaporation of the chemical solution (aqua regia) can be reduced and also the chemical solution can be further stabilized. Therefore, fabrication costs can be greatly reduced, compared to the known method. Furthermore, metal corrosion in an etching apparatus can be also reduced by reducing the treatment temperature.

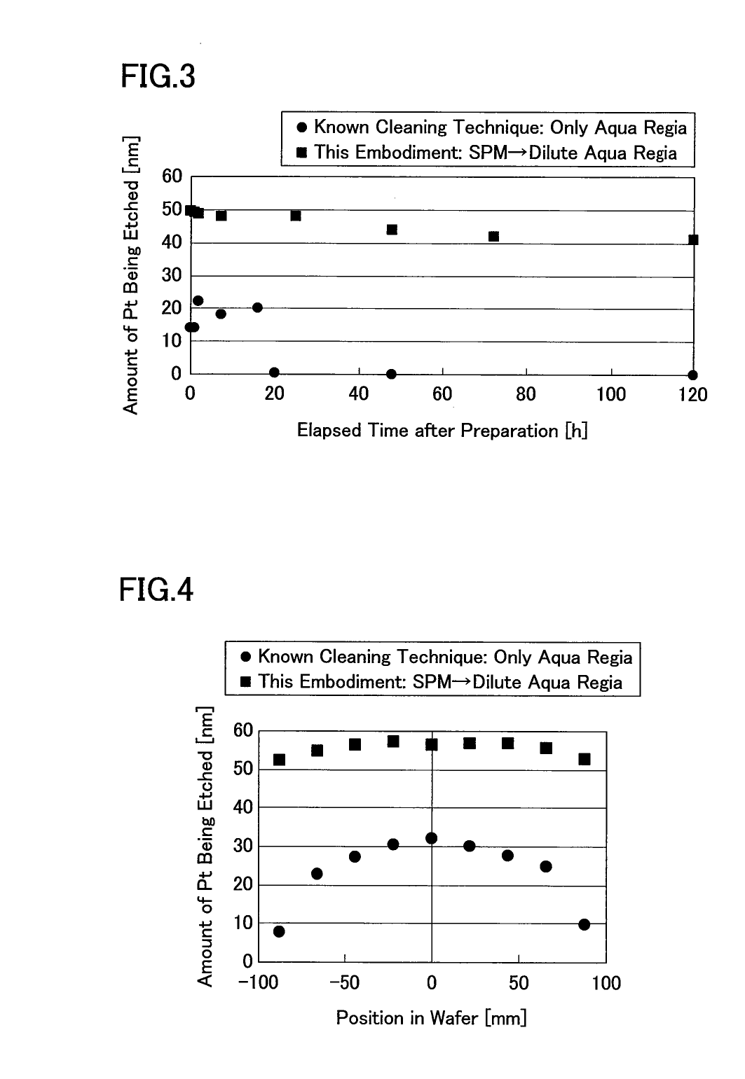

FIG. 3 is a graph showing the relationship between the amount of Pt being etched and an elapsed time since the preparation of aqua regia for the case where the method of the first embodiment was employed and the case where the known method was employed. Specifically, FIG. 3 shows results for the case where, after residual Pt particles remaining on a substrate was activated by carrying out SPM treatment (H₂SO₄:H₂O₂=1-5:1) at a temperature of 100 to 160° C., aqua regia treatment was performed to the activated Pt particles using dilute aqua regia (nitric acid:hydrochloric acid:water=1:5:4) at a temperature of 60° C. for 90 seconds (the method of this embodiment), and the case where activation of residual Pt particles was not performed and only aqua regia treatment using dilute aqua regia was performed (the known method).

As can be seen from FIG. 3, in the case where only aqua regia treatment using dilute aqua regia was performed, the amount of Pt being etched was not very large within 1 hour after the preparation of dilute aqua regia. Thereafter, the amount of Pt being etched increased, but Pt was not etched at all after the elapsed time since the preparation of dilute aqua regia exceeded 20 hours, and the lifetime of the chemical solution was short. In the case where Pt was activated by the above-described SPM treatment, on the other hand, the amount of Pt being etched was stable within 120 hours after the preparation of dilute aqua regia, and the amount was equal to or greater than twice of that in the case where Pt was not activated, and the lifetime of the chemical solution was very long. Presumably, this is because activated Pt can be dissolved with a lower nitrosyl chloride concentration than nonactivated Pt.

FIG. 4 is a graph showing the amount of Pt being etched at different positions in a wafer surface for the case where the method of the first embodiment was employed and the case where the known method was employed. FIG. 4 shows the distribution of the amount of Pt being etched in a wafer surface after a lapse of 3 hours since the preparation of dilute aqua regia for the case where, after residual Pt particles were activated by carrying out SPM treatment (H₂SO₄:H₂O₂=1-5:1, at a temperature of 100 to 160° C.) using a single wafer cleaning apparatus, cleaning with water for 120 seconds and drying for 60 seconds were carried out, and then, aqua regia treatment using dilute aqua regia (nitric acid:hydrochloric acid': water=1:5:4, at a treatment temperature of 60° C.) was carried out for 90 seconds (the method of this embodiment), and the case where only aqua regia treatment using dilute aqua regia was performed without performing activation of residual Pt particles.

As can be seen from FIG. 4, for the case where only aqua regia treatment using dilute aqua regia was carried out, the amount of Pt being etched at a peripheral portion of a wafer was much smaller than that at a center portion of the wafer. On the other hand, for the case where Pt particles were activated by the above-described SPM treatment, the amount of Pt being etched in a peripheral portion of a wafer was substantially equal to that in a center portion of the wafer, and was increased to be about five times that in the peripheral portion of the wafer in the case where Pt was not activated. The reason why the amount of Pt being etched was smaller at the peripheral portion of the wafer than at the center portion of the wafer when the known method was employed is presumably because aqua regia was rapidly flowing at the peripheral portion and thus could not stay there, the temperature of aqua regia supplied to at the peripheral portion of the wafer was reduced, and the like. On the other hand, the reason why reduction in amount of Pt being etched was suppressed at the periphery portion of the wafer according to this embodiment is presumably because Pt was activated and thus the etching rate was hardly reduced even when the temperature of aqua regia was reduced.

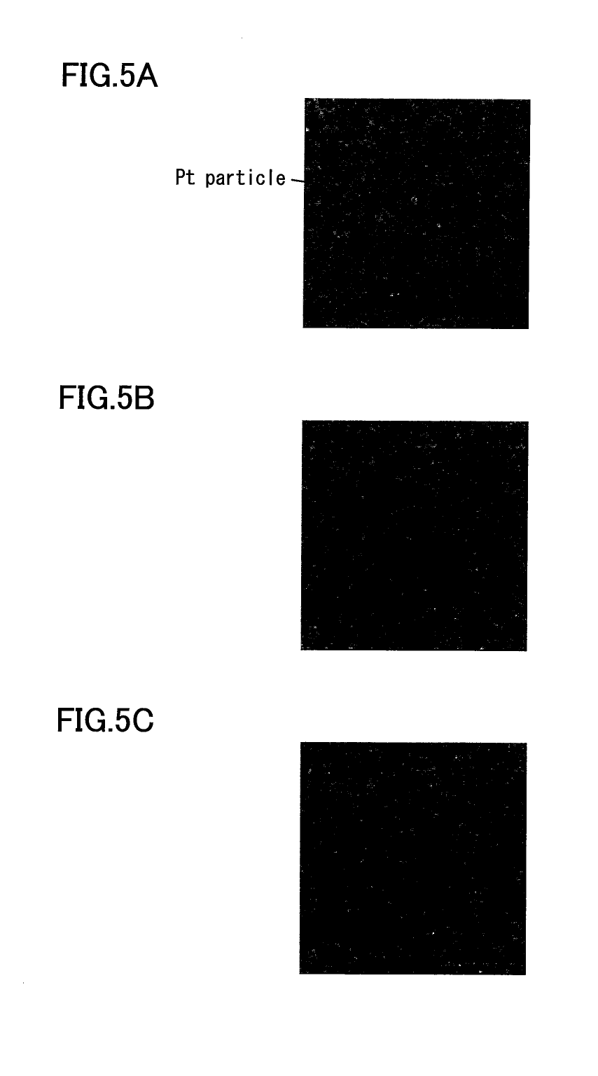

FIGS. 5A and 5B are scanning electron microscope (SEM) images of semiconductor substrates being cleaned according to the known method. FIG. 5C is a SEM image of a semiconductor substrate being cleaned according to the method of this embodiment. FIGS. 5A and 5B show results obtained by carrying out only aqua regia treatment using dilute aqua regia (nitric acid:hydrochloric acid:water=1:5:4) at a treatment temperature of 60° C. for 120 seconds and 180 seconds without activating residual Pt particles. FIG. 5C shows results obtained by carrying out, after activating residual Pt particles using SPM (H₂SO₄:H₂O₂=1-5:1) at a treatment temperature of 100 to 160° C., aqua regia treatment using dilute aqua regia (nitric acid:hydrochloric acid:water=1:5:4) at a treatment temperature of 60° C. for 30 seconds.

As can be seen from FIGS. 5A-5C, in the case where only aqua regia treatment using dilute aqua regia was performed, even after a lapse of 120 seconds since a start of the treatment, Pt particle were not removed and, at a lapse of 180 seconds, Pt particles were finally removed. On the other hand, in the case where Pt was activated by the above-described SPM treatment, Pt particles were completely removed by carrying out aqua regia treatment for only 30 seconds. As described above, according to the method of this embodiment, a treating time can be greatly reduced.

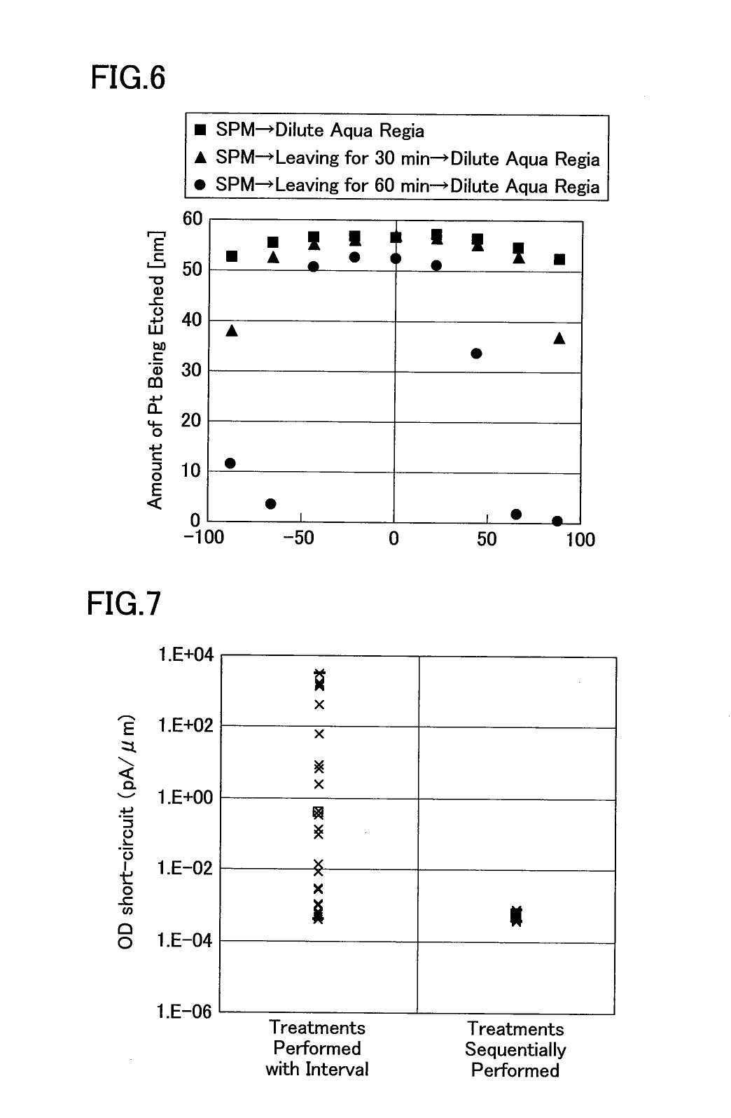

FIG. 6 is a graph showing the dependency of the amount of Pt being etched in a wafer surface by aqua regia treatment using dilute aqua regia on an elapsed time in which the wafer is left. The abscissa in FIG. 6 indicates a distance from a center of a wafer. FIG. 6 shows results obtained for the case where a time interval from an end of SPM discharge in the step of SPM treatment for activating Pt to a start of aqua regia treatment using dilute aqua regia in the step of aqua regia treatment for dissolving Pt particles was 4 minutes, 30 minutes and 60 minutes. In this case, after a wafer subjected to SPM treatment was cleaned with water for 120 seconds, the wafer was dried for 60 seconds, and then, was left in an atmosphere. The wafers were left standing in corresponding slot positions in a case for subsequent treatment by an apparatus.

As can be seen from FIG. 6, if the time between SPM treatment and aqua regia treatment using dilute aqua regia, in which a wafer is left is 30 minutes, the amount of Pt being etched at a peripheral portion of the wafer is large, almost as large as that at a center portion of the wafer. However, if the wafer is left for 60 minutes after SPM treatment, Pt was etched, but the amount of Pt being etched is remarkably reduced at the peripheral portion of the Pt wafer. Thus, in view of the amount of Pt being etched, the time between the step of activating Pt particles and the step of dissolving Pt particles, in which the wafer is left, is preferably limited to 30 minutes or less. It is assumed that, when the time in which the wafer is left is increased, activated Pt radicals are influenced by oxygen in an atmosphere and then disappear, or the surface potential of Pt particles returns to a previous state, and thus, the amount of Pt being etched is reduced. If the wafer is kept, after being cleaned and dried in the step of SPM treatment, in an atmosphere which does not contain oxygen, such as, for example, a nitrogen atmosphere, the time elapsed before aqua regia treatment using dilute aqua regia can be increased to 30 minutes or more.

FIG. 7 is a diagram showing results of an electrical isolation evaluation (short-circuit current measurement) between adjacent active regions (OD) with an isolation region interposed therebetween for the case where the step of activating Pt particles by SPM treatment and the step of dissolving Pt particles using dilute aqua regia for 30 seconds were performed with a 60 minute interval therebetween, and the case where the two steps were sequentially performed. In this case, the step of activating Pt particles was performed using SPM (H₂SO₄:H₂O₂=1-5:1), at a treatment temperature of 100 to 160° C., and the step of dissolving Pt particles was performed using dilute aqua regia (nitric acid:hydrochloric acid:water=1:5:4) at a treatment temperature of 60° C.

As can be seen from FIG. 7, when aqua regia treatment was carried out using dilute aqua regia after a lapse of 60 minutes since SPM treatment, an short-circuit deficiency between active regions (OD) occurred many times. In contrast, when aqua regia treatment was carried out using dilute aqua regia immediately after SPM treatment, OD short-circuit deficiency did not occur. In this case, whether or not short-circuit deficiencies have occurred is determined based on whether or not a leakage current is 1×10⁻² pA/μm or more. Thus, in view of evaluation of OD short-circuit, the time between the step of activating Pt particles and the step of dissolving Pt particles, in which the wafer is left, is preferably limited to 60 minutes or less.

As described above, when, after Pt is activated by treatment with a chemical solution obtained by adding an oxidant to a sulfuric acid based solution, aqua regia treatment using aqua regia or dilute aqua regia is carried out, Pt surfaces are activated, and thereby, Pt can be easily dissolved. Thus, the lifetime of aqua regia can be increased to be six-fold, compared to the known method. Also, since Pt surfaces are activated and thus Pt is easily dissolved, the Pt etching rate can be improved to be twice or more than twice that in the known method in carrying out aqua regia treatment using aqua regia or dilute aqua regia. As a result, the time of treatment with a chemical solution can be reduced to half or less than half, so that the operation rate of an etching apparatus can be greatly improved and corrosion of the etching apparatus per treatment can be reduced, compared to the known method. As described above, according to the cleaning method of this embodiment, the effect of removing Pt is dramatically improved, compared to the case where only SPM is employed and the case where only dilute aqua regia is used, and a synergistic effect by using both SPM and dilute aqua regia can be achieved.

Note that in this embodiment, aqua regia (sulfuric acid:hydrochloric acid=1:3-7, at a temperature of 40° C. or more and 70° C. or less) or a dilute solution obtained by diluting aqua regia 7-fold or less with water is used as a solution for dissolving residual Pt. However, the solution for dissolving residual Pt is not limited thereto, but may be a chemical solution containing chlorine and an oxidant. For example, even when a mixture solution of hydrochloric acid and hydrogen peroxide water (HCl:H₂O₂=3-5:1, at a treatment temperature of 40° C. or more and 70° C. or less), a mixture solution of hydrochloric acid and ozone water (HCl:O₃=3-5:1, at a treatment temperature of 40° C. or more and 70° C. or less), a solution obtained by mixing potassium permanganate to hydrochloric acid (KMnO₄: 1-7 wt %, at a treatment temperature of 40° C. or more and 70° C. or less), a solution obtained by mixing chromium trioxide to hydrochloric acid (CrO₃: 1-5 wt %, at a treatment temperature of 40° C. or more and 70° C. or less), a solution obtained by mixing potassium chlorate to hydrochloric acid (KClO₃: 1-7 wt %, at a treatment temperature of 40° C. or more and 70° C. or less), a solution obtained by mixing osmium tetraoxide to hydrochloric acid (OsO₄: 1-6 wt %, at a treatment temperature of 40° C. or more and 70° C. or less), or a dilute solution obtained by diluting any one of the above-described solutions 7-fold or less with water is used, the same effects as those obtained using aqua regia can be achieved.

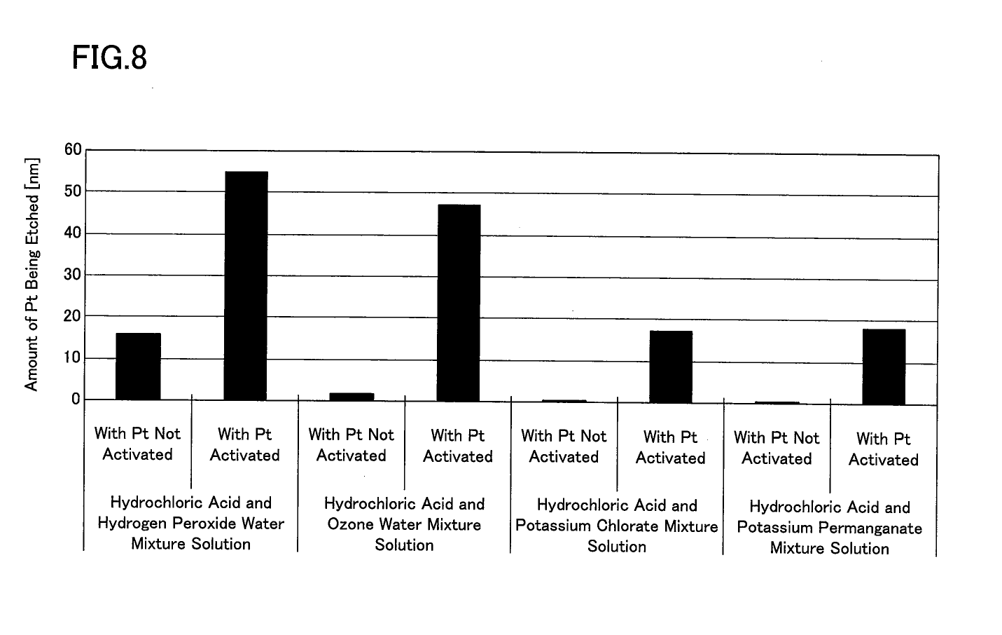

FIG. 8 is a graph showing the amount of Pt being etched using a mixture solution of hydrochloric acid and an oxidant for the case where the known method was employed (represented by “with Pt not activated” in FIG. 8) and the case where the method of the first embodiment was employed (represented by “with Pt activated” in FIG. 8). FIG. 8 shows, as examples of a solution for dissolving residual Pt, a mixture solution of hydrochloric acid and hydrogen peroxide water (HCl:H₂O₂=5:1, at a treatment temperature of 50° C.), a mixture solution of hydrochloric acid and ozone water (HCl:O₃=5:1, at a treatment temperature of 50° C.), a solution obtained by mixing hydrochloric acid to potassium chlorate (KClO₃: 5 wt %, at a treatment temperature of 50° C.), and a mixture solution of hydrochloric acid and potassium permanganate (KMnO₄: 5 wt %, at a treatment temperature of 50° C.), and results obtained for each of the solutions by performing treatment for 90 seconds. As SPM, a solution represented by H₂SO₄:H₂O₂=1-5:1 was used.

As can be seen from FIG. 8, for each of the solutions, the amount of Pt being etched was dramatically increased by carrying out SPM treatment, and thus, Pt was dissolved. As described above, the results show that even when a mixture solution of hydrochloric acid and an oxidant is used, Pt can be effectively removed by combination with SPM treatment. Moreover, the above-described chemical solutions containing chlorine and an oxidant, i.e., a mixture solution of hydrochloric acid and hydrogen peroxide water (HCl:H₂O₂=3-5:1, at a treatment temperature of 40° C. or more and 70° C. or less), a mixture solution of hydrochloric acid and ozone water (HCl:O₃=3-5:1, at a treatment temperature of 40° C. or more and 70° C. or less), a solution obtained by mixing potassium permanganate to hydrochloric acid (KMnO₄: 1-7 wt %, at a treatment temperature of 40° C. or more and 70° C. or less), a solution obtained by mixing chromium trioxide to hydrochloric acid (CrO₃: 1-5 wt %, at a treatment temperature of 40° C. or more and 70° C. or less), a solution obtained by mixing potassium chlorate to hydrochloric acid (KClO₃: 1-7 wt %, at a treatment temperature of 40° C. or more and 70° C. or less), a solution obtained by mixing osmium tetraoxide to hydrochloric acid (OsO₄: 1-6 wt %, at a treatment temperature of 40° C. or more and 70° C. or less), and a dilute solution obtained by diluting any one of the above-described solutions 7-fold or less with water are chemical solutions which are less corrosive than aqua regia or dilute aqua regia. Thus, the effect of suppressing progression of corrosion on metal parts of an etching apparatus can be achieved. Therefore, even when treatment is carried out with the same apparatus used for activating Pt surfaces, a high level of safety can be ensured, and also, contamination can be prevented using an even less expensive apparatus.

The treatment sequence when a multi-chamber apparatus such as 2-chamber apparatus or the like is used is as follows. First, a chemical solution for activating Pt is prepared in one chamber. Thereafter, after cleaning with water is performed for 120 seconds and, if necessary, drying for 60 seconds is carried out, a chemical solution for dissolving Pt is prepared in the other chamber, and then cleaning with water and then drying are performed, respectively, for 120 seconds and for 60 seconds. The treatment sequence with a 1-chamber multi-process apparatus which includes one chamber and is capable of performing a plurality of chemical solution treatments includes preparing a chemical solution for activating Pt, performing cleaning with water for 120 seconds, preparing for a chemical solution for dissolving Pt, and then performing cleaning with water and drying for 120 seconds and 60 seconds, respectively.

In this embodiment, it has been described that a time between the step of activating Pt particles and the step of dissolving Pt particles using aqua regia or a dilute solution obtained by diluting aqua regia 7-fold or less with water, in which a wafer is left, is preferably limited to 30 minutes or less. It is also preferable that a time in which a wafer is left between the step of activating Pt particles and the step of dissolving Pt particles using each of the above-described chemical solutions containing other chlorine and an oxidant is limited to 30 minutes or less.

Note that, as an etching apparatus for performing the step of activating Pt particles and the step of removing Pt, a single wafer cleaning apparatus or a disposal spray type wafer cleaning apparatus is preferably used because particle transcription onto a wafer in the same treatment chamber can be prevented, compared to treatment using a batch type wafer cleaning apparatus.

### Second Embodiment

A method for fabricating a semiconductor device according to a second embodiment of the present invention will be described with reference to the accompanying drawings. Note that each member also described in the first embodiment is identified by the same reference numeral, and therefore, the description thereof will be omitted.

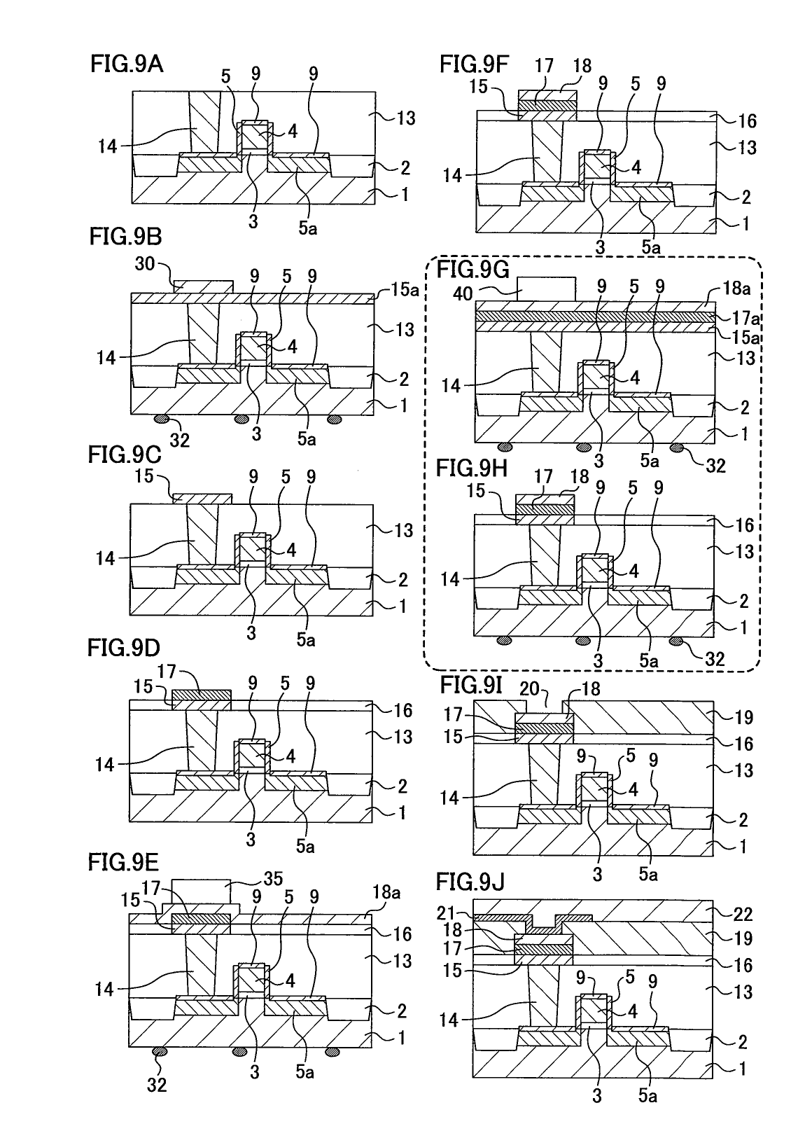

FIGS. 9A-9J are cross-sectional views illustrating respective steps for fabricating a FeRAM according to the second embodiment. The FeRAM of this embodiment is formed by combining a capacitor device including lower and upper electrodes made of Pt with a ferroelectric film interposed therebetween, and a MOS transistor.

First, in the step shown in FIG. 9A, a MOS transistor, which has been described in the first embodiment, is formed on a semiconductor substrate 1 of silicon. Next, after a first interlevel insulation film 13 of a silicon oxide film is formed on the semiconductor substrate 1 by CVD, a contact hole formation region for forming a contact hall electrically connected to source/drain diffused layer of the MOS transistor is formed by etching, and then, a Ti film and a tungsten film are formed in the hole in this order, thereby forming a contact plug 14.

Next, in the step shown in FIG. 9B, after a Pt film 15a to be a lower electrode 15 of a capacitor device is formed, a hard mask 30 is formed on the Pt film 15a so as to have a predetermined shape.

Next, in the step shown in FIG. 9C, after parts of a Pt surface located on regions from which the Pt surface is desired to be removed are activated by treatment using SPM (H₂SO₄:H₂O₂=1-5:1) at a temperature of 80° C. or more and 160° C. or less, unnecessary Pt is removed using aqua regia (nitric acid:hydrochloric acid=1:3-7) or a dilute solution, obtained by diluting aqua regia 7-fold or less with water, at a temperature of 40° C. or more and 70° C. or less, thereby forming the lower electrode 15.

Next, in the step shown in FIG. 9D, after a second interlevel insulation film 16 of a silicon oxide film is formed on the semiconductor substrate 1, polishing (chemical mechanical polishing: CMP) is performed to have an upper surface of the lower electrode 15 exposed. Next, after a ferroelectric film of, for example, PZT or the like is formed on the lower electrode 15 and the second interlevel insulation film 16, a photoresist pattern or a hard mask is formed on the ferroelectric film so as to have a predetermined shape, and then, unnecessary part of the ferroelectric film is removed by dry etching. Thereafter, the hard mask is also removed. Thus, a ferroelectric film 17 having the predetermined shape is formed.

Next, in the step shown in FIG. 9E, after a Pt film 18a to be an upper electrode 18 of the capacitor device is formed on the second interlevel insulation film 16 and the ferroelectric film 17, a hard mask 35 having a predetermined shape is formed on the Pt film.

Next, in the step shown in FIG. 9F, parts of a Pt surface located on regions from which the Pt surface is desired to be removed are activated by treatment using SPM (H₂SO₄:H₂O₂=1-5:1) at a temperature of 80° C. or more and 160° C. or less. Subsequently, unnecessary Pt is removed using aqua regia (nitric acid:hydrochloric acid=1:3-7) or a dilute solution, obtained by diluting aqua regia 7-fold or less with water, at a temperature of 40° C. or more and 70° C. or less, thereby forming the upper electrode 18.

In the steps of 9B through 9F, the lower electrode 15, the ferroelectric film 17 and the upper electrode 18 of the capacitor device are separately patterned and formed. However, as shown in FIGS. 9G and 9H, a photoresist pattern or a hard mask 40 may be formed so as to have a predetermined shape after a Pt film to be lower electrode 15 of a capacitor device, the ferroelectric film 17 of PZT or the like, a Pt film to be the upper electrode 18 of the capacitor device are sequentially formed, and then, unnecessary parts of the Pt films as upper and lower layers and the ferroelectric film as a middle layer may be removed together at a time by dry etching, thereby forming the capacitor device.

Next, in the step shown in FIG. 9I, after a third interlevel insulation film 19 of a silicon oxide film is formed on the semiconductor substrate 1 so as to cover the capacitor device, an opening 20 for providing connection between an upper interconnect 21 and the upper electrode 18 is formed in part of the third interlevel insulation film 19 located on the upper electrode 18 by dry etching.

Next, as shown in FIG. 9J, after a metal film is formed on the semiconductor substrate so as to fill the opening 20, the metal film is patterned so as to have a predetermined shape, thereby forming an upper interconnect 21. Thereafter, a fourth interlevel insulation film 22 of a silicon nitride film or the like is formed on the semiconductor substrate 1, thereby forming a semiconductor memory device including a ferroelectric capacitor device.

In the method for fabricating a semiconductor device according to this embodiment, a Pt contaminant 32 is attached to a back surface of the semiconductor substrate 1 after the Pt film 15a shown in FIG. 9B is formed, after the Pt film 18a shown in FIG. 9E to be the upper electrode 18 is formed, after the Pt film shown in FIGS. 9G and 9H to be the lower electrode 15, the PZT film 17a to be the ferroelectric film 17 and the Pt film 18a to be the upper electrode 18 are formed, and after unnecessary Pt and PZT are removed at a time by dry etching.

As described above, if the amount of the Pt contaminant remaining on the back surface of the substrate or an insulation film on the substrate back surface is larger than 1×10¹⁰ atom/cm², the lifetime and electric characteristics of the capacitor device are adversely affected. On the other hand, even when SPM (sulfuric acid and peroxide mixture solution) or HPM (hydrochloric acid peroxide mixture solution), which are general metal removal chemical solutions, is used to remove the Pt contaminant on the back surface of the substrate, Pt is only dissolved in aqua regia, and thus, the Pt contaminant cannot be reduced. Thus, to reduce the Pt contaminant on the back surface of the substrate, aqua regia or dilute aqua regia is used.

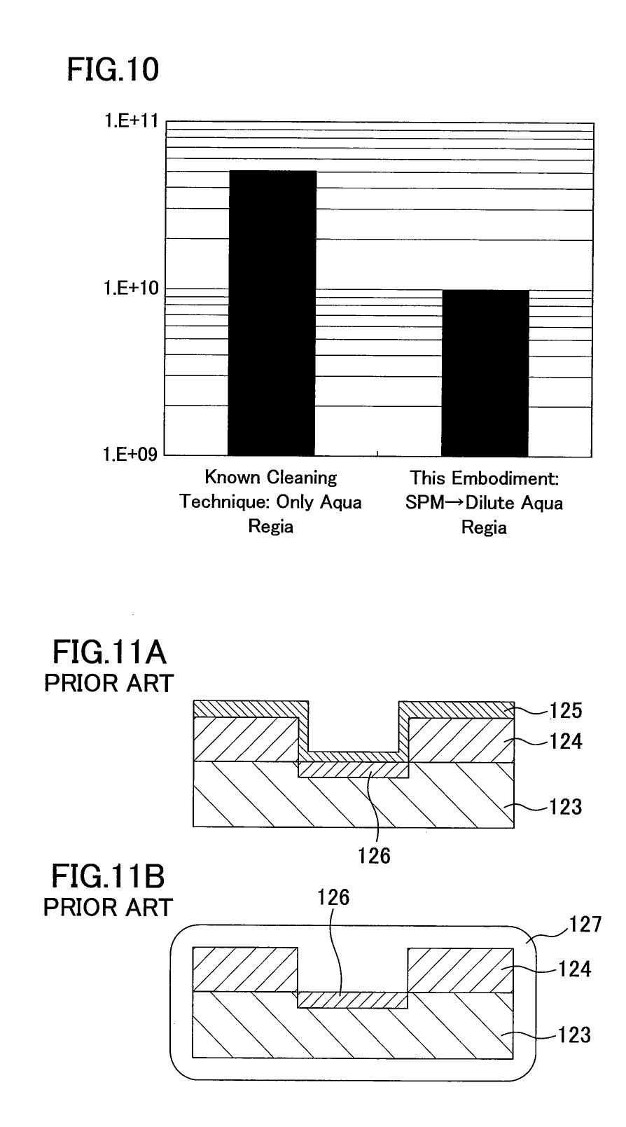

FIG. 10 is a graph showing evaluation results of the amount of a Pt contaminant on a back surface of a substrate by means of ICP-MS (inductively-coupled plasma source mass spectrometry) for the case where only aqua regia treatment using dilute aqua regia (nitric acid:hydrochloric acid:water=1:5:4, at a treatment temperature of 60° C.) was performed for 60 seconds and the case where the method of this embodiment was used. As the method of this embodiment, the case where SPM (H₂SO₄:H₂O₂=1-5:1) treatment was performed to activate Pt, and treatment using dilute aqua regia (nitric acid:hydrochloric acid:water=1:5:4, at a treatment temperature of 60° C., for a treatment time of 60 seconds) was carried out is shown.

As can be seen from FIG. 10, in the case where only aqua regia treatment with dilute aqua regia was performed, the amount of the Pt contaminant remaining on the back surface of the substrate is about 5×10¹⁰ atoms/cm². In contrast, in the case where aqua regia treatment was carried out by the method of this embodiment, the amount of the Pt contaminant was reduced to 1×10¹⁰ atoms/cm² or less.

In this embodiment, after the Pt film 15a of FIG. 9B to be the lower electrode 15 is formed, after the Pt film 18a of FIG. 19E to be the upper electrode 18, or after the Pt film 15a, the PZT film 17a and the Pt film 18a of FIG. 9H are formed, unnecessary Pt and PZT are removed at a time by dry etching, SPM (H₂SO₄:H₂O₂=1-5:1, at a treatment temperature of 80° C. or more and 160° C. or less) treatment is performed to the back surface of the substrate to activate Pt, and then, unnecessary Pt is removed using aqua regia (nitric acid:hydrochloric acid=1:3-7, at a temperature of 40° C. or more and 70° C. or less) or a dilute solution obtained by diluting aqua regia 7-fold or less with water. Also, as the above-described results show, according to the method of this embodiment, a Pt contaminant attached to the back surface of the substrate can be reduced to a level which does not adversely affect the lifetime and electrical characteristics of a capacitor device.

Moreover, as described above with reference to FIG. 3 in the first embodiment, when Pt is activated using SPM (H₂SO₄:H₂O₂=1-5:1, at a treatment temperature of 100° C. or more and 160° C. or less), Pt is stably etched until 120 hours after the preparation of SPM, and furthermore, the amount of Pt being etched is improved to be twice or more than twice that in the case where activation treatment.

This etching method is used in this embodiment. Thus, as shown in FIGS. 9C and 9F, the solution lifetime of aqua regia is increased to be 6 times or more than 6 times that in the known method by carrying out aqua regia treatment after Pt is activated by SPM treatment, and the amount of Pt being etched is increased to be twice or more than twice that in the known method, so that a treatment time can be reduced to half or less than half and an operation rate of the apparatus can be greatly improved. Moreover, treatment can be carried out at a relatively low temperature, i.e., a temperature of 40° C. or more and 70° C. or less, and thus, evaporation and alteration of aqua regia can be suppressed. In addition, compared to the case where the lower electrode 15 and the upper electrode 18 are formed by dry etching, Pt contamination on the back surface of the substrate can be effectively prevented without increasing the number of steps.

In this embodiment, as in the first embodiment, a time from an end of discharge of a chemical solution in the step of activating Pt particles to a start of discharge of aqua regia in the step of dissolving Pt particles using aqua regia or a dilute solution obtained by diluting aqua regia 7-fold or less with water is preferably limited to 30 minutes or less.

Moreover, as a solution for activating Pt, besides SPM, a chemical solution obtained by adding an oxidant to a sulfuric acid based solution, a mixture solution of sulfuric acid and ozone water (H₂SO₄:O₃=1:1-5, a treatment temperature of 80° C. or more and 160° C. or less), an electrolytic sulfuric acid solution (at a treatment temperature of 80° C. or more and 100° C. or less) or like solution can be used to achieve the same effects as those described above.

In this embodiment, as the lower electrode and the upper electrode, other than Pt, a noble metal film formed of a single layer of any one of, or a stacked layer of two or more of Ir (iridium), Pd (palladium), Rh (rhodium), Ru (ruthenium), and Os (osmium) may be used. Assume that Ir is used as the lower electrode or the upper electrode. In such a case, in order to activate Ir, treatment using a chemical solution having an oxidation-reduction potential of 1.0 V or more is carried out, and thus, an active Ir radical is formed. Examples of a chemical solution for activating Ir include SPM (H₂SO₄:H₂O₂=3-8:1, at a treatment temperature of 60° C. or more and 140° C. or less), a mixture solution of sulfuric acid and ozone water (H₂SO₄: O₃=3-8:1, at a treatment temperature of 60° C. or more and 140° C. or less), an electrolytic sulfuric acid solution (at a treatment temperature of 60° C. or more and 100° C. or less), and like solution.

In this embodiment, a solution used in the step of dissolving a noble metal such as unnecessary Pt in forming the lower electrode and the upper electrode, and the step of removing a noble metal contaminant such as a Pt contaminant attached to the back surface of the substrate, aqua regia (nitric acid:hydrochloric acid=1:3-7, at a treatment temperature of 40° C. or more and 70° C. or less) or a dilute solution obtained by diluting aqua regia 7-fold or less with water is used. However, the solution is not limited thereto, but may be any chemical solution containing chlorine and an oxidant. For example, when a mixture solution of hydrochloric acid and hydrogen peroxide water (HCl:H₂O₂=3-5:1, at a treatment temperature of 40° C. or more and 70° C. or less), a mixture solution of hydrochloric acid and ozone water (HCl:O₃=3-5:1, at a treatment temperature of 40° C. or more and 70° C. or less), a solution obtained by mixing potassium permanganate to hydrochloric acid (KMnO₄: 1-7 wt %, at a treatment temperature of 40° C. or more and 70° C. or less), a solution obtained by mixing chromium trioxide to hydrochloric acid (CrO₃: 1-5 wt %, at a treatment temperature of 40° C. or more and 70° C. or less), a solution obtained by mixing potassium chlorate to hydrochloric acid (KClO₃: 1-7 wt %, at a treatment temperature of 40° C. or more and 70° C. or less), a solution obtained by mixing osmium tetraoxide to hydrochloric acid (OsO₄: 1-6 wt %, at a treatment temperature of 40° C. or more and 70° C. or less), or a 1-7-fold diluted solution of any one of the solutions with water is used, the same effects can be achieved. Each of the above-described solutions is less corrosive than aqua regia or dilute aqua regia, but can dissolve a noble metal such as Pt when being used after the noble metal such as Pt is activated. Furthermore, since the above-described solutions are less corrosive than aqua regia or dilute aqua regia, the above-described solutions can exhibit the effect of suppressing progression of corrosion on metal parts of the etching apparatus. Therefore, even when treatment is carried out with the same apparatus used for activating Pt surfaces, a high level of safety can be ensured, and also, contamination can be prevented using an even less expensive apparatus.

In this embodiment, it is preferable to limit a time from an end of discharge of SPM in the step of activating Pt particles to a start of discharge of aqua regia or dilute aqua regia in the step of dissolving Pt particles using aqua regia or a dilute solution obtained by diluting aqua regia 7-fold or less with water to 30 minutes or less. It is also preferable to limit a time from an end of discharge of a chemical solution in the step of activating Pt particles to a start of discharge of a chemical solution in the step of dissolving Pt particles using each of the above-described chemical solutions containing some other chlorine and an oxidant to 30 minutes or less.

It is more preferable to use a single wafer cleaning apparatus or a disposal spray type cleaning apparatus as an etching apparatus for performing the step of activating Pt and the step of removing Pt because particle transcription onto a wafer can be prevented by using such an apparatus, compared to the case where a batch type cleaning apparatus.

In the method of this embodiment, the lower electrode 15 and the upper electrode 18 are formed while Pt is activated and dissolved. However, after the lower electrode 15 and the upper electrode 18 are individually formed by dry etching, Pt remaining on the back surface of the substrate may be removed using SPM and aqua regia or the like.

In the semiconductor device according to each of the above-described embodiments, besides the semiconductor substrate, a semiconductor substrate, an OSI substrate including a semiconductor layer containing silicon and the like may be used.

As has been described, a method for fabricating a semiconductor device according to an embodiment of the present invention is useful for a semiconductor device including a silicide containing a noble metal, a semiconductor device including an electrode using a noble metal, and the like.

The foregoing description illustrates and describes the present disclosure. Additionally, the disclosure shows and describes only the preferred embodiments of the disclosure, but, as mentioned above, it is to be understood that it is capable of changes or modifications within the scope of the concept as expressed herein, commensurate with the above teachings and/or skill or knowledge of the relevant art. The described hereinabove are further intended to explain best modes known of practicing the invention and to enable others skilled in the art to utilize the disclosure in such, or other embodiments and with the various modifications required by the particular applications or uses disclosed herein. Accordingly, the description is not intended to limit the invention to the form disclosed herein. Also it is intended that the appended claims be construed to include alternative embodiments.

What is claimed is:

1. A method for fabricating a semiconductor device, the method comprising the steps of:
a) forming a metal film containing a noble metal on a substrate including a semiconductor layer containing silicon or a conductive film containing silicon formed on the substrate;
b) forming, after the step a), a silicide film containing the noble metal on the substrate or the conductive film by performing thermal treatment to the substrate to cause the noble metal and silicon react with each other;
c) activating, after the step b), unreacted part of the noble metal using a first chemical solution; and
d) dissolving the unreacted part of the noble metal activated in the step c) using a second chemical solution,
wherein
the step d) is performed within 30 minutes after performing the step c).

2. The method of claim 1, wherein
the noble metal is platinum, the first chemical solution is a mixture solution of a sulfuric acid based solution and an oxidant, and the second chemical solution is a mixture solution of a hydrochloric acid based solution and an oxidant.

3. The method of claim 1, wherein
the first chemical solution is a solution selected from the group consisting of a mixture solution of sulfuric acid and hydrogen peroxide water, a mixture solution of sulfuric acid and ozone water, and an electrolytic sulfuric acid solution.

4. The method of claim 3, wherein
in the step c), the first chemical solution is used at a solution temperature of 80° C. or more.

5. The method of claim 3, wherein
a mix ratio of sulfuric acid and hydrogen peroxide water in the mixture solution of sulfuric acid and hydrogen peroxide water as the first chemical solution is 1-5:1, or a mix ratio of sulfuric acid and ozone water in the mixture solution of sulfuric acid and ozone water as the first chemical solution is 1-5:1.

6. The method of claim 1, wherein
the second chemical solution is a solution selected from the group consisting of a mixture solution of nitric acid and hydrochloric acid, a mixture solution of hydrochloric acid and hydrogen peroxide water, a mixture solution of hydrochloric acid and ozone water, a solution obtained by mixing potassium permanganate to hydrochloric acid, a solution obtained by mixing chromium trioxide to hydrochloric acid, a solution obtained by mixing potassium chlorate to hydrochloric acid, a solution obtained by mixing osmium tetraoxide to hydrochloric acid, and a dilute solution of any one of the solutions.

7. The method of claim 6, wherein
in the step c), the second chemical solution is used at a solution temperature of 40° C. or more.

8. The method of claim 6, wherein
a mix ratio of nitric acid and hydrochloric acid in the mixture solution of nitric acid and hydrochloric acid is 1:3-7, a mix ratio of hydrochloric acid and hydrogen peroxide water in the mixture solution of hydrochloric acid and hydrogen peroxide water is 3-5:1, a mix ratio of hydrochloric acid and ozone water in the mixture solution of hydrochloric acid and ozone water is 3-5:1, the solution obtained by mixing potassium permanganate to hydrochloric acid is a solution obtained by mixing 1-7 wt % of potassium permanganate to hydrochloric acid, the solution obtained by mixing chromium trioxide to hydrochloric acid is a solution obtained by mixing 1-5 wt % of chromium trioxide to hydrochloric acid, the solution obtained by mixing potassium chlorate to hydrochloric acid is a solution obtained by mixing 1-7 wt % of potassium chlorate to hydrochloric acid, the solution obtained by mixing osmium tetraoxide to hydrochloric acid is a solution obtained by mixing 1-6 wt % of osmium tetraoxide to hydrochloric acid, and a dilution degree in the dilute solution of any one of the solutions is 7-fold or less.

9. A method for fabricating a semiconductor device, the method comprising the steps of:
a) forming a first metal film containing a first noble metal on an interlevel insulation film formed on a substrate;
b) removing, after the step a), a contaminant containing the first noble metal attached to a back surface of the substrate;
c) forming, after the step a), a lower electrode by selectively removing the first metal film;
d) forming a capacitive insulation film on the lower electrode;
e) forming a second metal film containing a second noble metal on the capacitive insulation film and the substrate;
f) removing, after the step e), a contaminant containing the second noble metal attached to the back surface of the substrate; and
g) forming, after the step e), an upper electrode by selectively removing the second metal film.

10. The method of claim 9, wherein
the step b) is performed simultaneously with the step c), and in the step b) and the step c), the first noble metal is activated using a mixture solution of a sulfuric acid based solution and an oxidant as a first chemical solution, and then, the first noble metal is dissolved using a mixture solution of a hydrochloric acid based solution and an oxidant as a second chemical solution, and
the step f) is performed simultaneously with the step g), and in the step f) and step g), the second noble metal is activated using the first chemical solution, and then, the second noble metal is dissolved using the second chemical solution.

11. The method of claim 10, wherein
in the step b) and the step c), treatment for dissolving the first noble metal using the second chemical solution is performed within 30 minutes or less after treatment for activating the first noble metal using the first chemical solution, and
in the step f) and the step g), treatment for dissolving the second noble metal using the second chemical solution is performed within 30 minutes or less after treatment for activating the second noble metal using the first chemical solution.

12. A method for fabricating a semiconductor device, the method comprising the steps of:
a) forming a first metal film containing a first noble metal, an insulation film and a second metal film containing a second noble metal in this order on an interlevel insulation film formed on a substrate:
b) forming a lower electrode of the first metal film, a capacitive insulation film of the insulation film, and an upper electrode of the second metal film by selectively removing parts of the second metal film, the insulation film, and the first metal film together at a time; and
c) removing, after the step of b), a contaminant containing the first noble metal and the second noble metal attached to a back surface of the substrate.

13. The method of claim 12, wherein
in the step c), the first noble metal and the second noble metal are activated using a mixture solution of a sulfuric acid based solution and an oxidant as a first chemical solution, and the first noble metal and the second noble metal are dissolved using a mixture solution of a hydrochloric acid based solution and an oxidant as a second chemical solution.

14. The method of claim 13, wherein
in the step c), treatment for dissolving the first noble metal and the second noble metal using the second chemical solution is performed within 30 minutes or less after treatment for activating the first noble metal and the second noble metal using the first chemical solution.

15. The method of claim 10, wherein
the first chemical solution is a solution selected from the group consisting of a mixture solution of sulfuric acid and hydrogen peroxide water, a mixture solution of sulfuric acid and ozone water, and an electrolytic sulfuric acid solution.

16. The method of claim 10, wherein
the first chemical solution is used at a solution temperature of 80° C. or more.

17. The method of claim 15, wherein
a mix ratio of sulfuric acid and hydrogen peroxide water in the mixture solution of sulfuric acid and hydrogen peroxide water as the first chemical solution is 1-5:1, or a mix ratio of sulfuric acid and ozone water in the mixture solution of sulfuric acid and ozone water as the first chemical solution is 1-5:1.

18. The method of claim 10, wherein
the second chemical solution is a solution selected from the group consisting of a mixture solution of nitric acid and hydrochloric acid, a mixture solution of hydrochloric acid and hydrogen peroxide water, a mixture solution of hydrochloric acid and ozone water, a solution obtained by mixing potassium permanganate to hydrochloric acid, a solution obtained by mixing chromium trioxide to hydrochloric acid, a solution obtained by mixing potassium chlorate to hydrochloric acid, a solution obtained by mixing osmium tetraoxide to hydrochloric acid, and a dilute solution of any one of the solutions.

19. The method of claim 18, wherein
the second chemical solution is used at a solution temperature of 40° C. or more.

20. The method of claim 18, wherein
a mix ratio of nitric acid and hydrochloric acid in the mixture solution of nitric acid and hydrochloric acid is 1:3-7, a mix ratio of hydrochloric acid and hydrogen peroxide water in the mixture solution of hydrochloric acid and hydrogen peroxide water is 3-5:1, a mix ratio of hydrochloric acid and ozone water in the mixture solution of hydrochloric acid and ozone water is 3-5:1, the solution obtained by mixing potassium permanganate to hydrochloric acid is a solution obtained by mixing 1-7 wt % of potassium permanganate to hydrochloric acid, the solution obtained by mixing chromium trioxide to hydrochloric acid is a solution obtained by mixing 1-5 wt % of chromium trioxide to hydrochloric acid, the solution obtained by mixing potassium chlorate to hydrochloric acid is a solution obtained by mixing 1-7 wt % of potassium chlorate to hydrochloric acid, the solution obtained by mixing osmium tetraoxide to hydrochloric acid is a solution obtained by mixing 1-6 wt % of osmium tetraoxide to hydrochloric acid, and a dilution degree in the dilute solution of any one of the solutions is 7-fold or less.
